(19) United States
(12) Patent Application Publication
(10) Pub. No.: US 2025/0132670 A1
(43) Pub. Date: Apr. 24, 2025

(54) CURRENT BALANCING CIRCUITS AND TECHNIQUES

(71) Applicant: Texas Instruments Incorporated, Dallas, TX (US)

(72) Inventors: Yueming Sun, Shanghai (CN); Yuqing Wu, Shanghai (CN)

(21) Appl. No.: 18/491,368

(22) Filed: Oct. 20, 2023

(51) Int. Cl. H02M 3/156; H03F 1/02

(52) U.S. Cl. CPC H02M 3/156; H03F 1/0227; H03F 2200/102

(57) ABSTRACT

Current balancing techniques. In an example, a circuit includes a synchronization terminal, an error amplifier, and a clock generator. The error amplifier is configured to generate a first control voltage signal based on a reference voltage and a power converter output voltage. The clock generator is configured to produce an outgoing clock signal having an outgoing clock frequency. The circuit further includes an encoder, a frequency detector, and a decoder. The encoder is coupled to the clock generator and synchronization terminal, and configured to encode the outgoing clock signal based on the first control voltage signal to provide, at synchronization terminal, an outgoing encoded clock signal. The frequency detector is coupled to synchronization terminal and configured to derive, from an incoming encoded clock signal, an incoming clock frequency. The decoder is coupled to synchronization terminal and configured to derive, from the incoming encoded clock signal, a second control voltage signal.

### TECHNICAL FIELD

This description relates to power converters, and more particularly, to current balancing techniques for multi-phase power converters.

### BACKGROUND

Many electronic applications utilize power management technology, to ensure that the power delivered to the application circuitry meets certain specifications. For example, power management chips for high-performance microprocessors require high efficiency current driving capability with low output voltage ripple. Multi-phase DC-DC converters have multiple parallel channels that distribute current equally and can reduce output voltage ripple compared to single-channel DC-DC converters. However, mismatches between components in the multiple channels, such as power transistors, inductors, and controllers, can cause current imbalances and reduce efficiency. Accordingly, current balancing can be used to distribute current equally and avoid channel burnout. A number of non-trivial issues remain with respect to current balancing.

### SUMMARY

According to one example, there is provided a circuit that can be used for current balancing in a power converter. In one example, the circuit comprises an error amplifier configured to generate a first control voltage signal based on a reference voltage and a power converter output voltage, a synchronization terminal, and a clock generator configured to produce an outgoing clock signal having an outgoing clock frequency. The circuit further comprises an encoder coupled to the clock generator and to the synchronization terminal, the encoder configured to encode the outgoing clock signal based on the first control voltage signal to provide, at the synchronization terminal, an outgoing encoded clock signal. The circuit further comprises a frequency detector coupled to the synchronization terminal and configured to derive, from an incoming encoded clock signal, an incoming clock frequency. The circuit further comprises a decoder coupled to the synchronization terminal and configured to derive, from the incoming encoded clock signal, a second control voltage signal.

According to another example, a multi-phase DC-DC converter comprises a first DC-DC converter and a second DC-DC converter. The first DC-DC converter includes a first input terminal for receiving an input voltage, a first synchronization terminal, a feedback terminal, and a first output terminal. The second DC-DC converter includes a second input terminal for receiving the input voltage, a second synchronization terminal coupled to the first synchronization terminal, and a second output terminal coupled to the first output terminal. The first DC-DC converter may include: an amplifier having an input terminal coupled to the feedback terminal; a clock generator; a level shifter having an input coupled to an output of the clock generator and to an output of the amplifier; and an output coupled to the first synchronization terminal. The second DC-DC converter may include: a frequency detector coupled to the second synchronization terminal; an envelope detector coupled to the second synchronization terminal; and a control circuit coupled to the frequency detector and to the envelope detector.

According to another example, a multi-phase DC-DC converter system comprises a first DC-DC converter and a second DC-DC converter. The first DC-DC converter includes a first input terminal for receiving an input voltage, a first synchronization terminal, a feedback terminal, and a first output terminal. The second DC-DC converter includes a second input terminal for receiving the input voltage, a second synchronization terminal coupled to the first synchronization terminal, and a second output terminal coupled to the first output terminal. In one example, the first DC-DC converter includes: an amplifier having an input terminal coupled to the feedback terminal; a clock generator; and a ramp generator coupled to a clock output terminal of the clock generator. The first DC-DC converter may further include a comparator having a first comparator input terminal coupled to an amplifier output terminal of the amplifier, a second comparator input terminal coupled to a ramp output terminal of the ramp generator, and a comparator output terminal coupled to the first synchronization terminal. In one example, the second DC-DC converter further includes a frequency detector coupled to the second synchronization terminal, a low pass filter coupled to the second synchronization terminal, and a control circuit coupled to the frequency detector and to the low pass filter.

### BRIEF DESCRIPTION OF THE DRAWINGS

FIG. 1A is a block diagram of an integrated circuit including current balancing circuitry, in an example.

FIG. 1B is a block diagram of a DC-DC converter including current balancing circuitry, in an example.

FIG. 2 is a block diagram of a multi-phase DC-DC converter including current balancing circuitry, in an example.

FIG. 3 is a schematic diagram illustrating current balancing circuitry in a multi-phase DC-DC converter, in an example.

FIG. 4 is a timing diagram illustrating various signals in the circuitry of FIG. 3, in an example.

FIG. 5 is a schematic diagram illustrating current balancing circuitry in a multi-phase DC-DC converter, in another example.

FIG. 6 is a timing diagram illustrating various signals in the circuitry of FIG. 5, in an example.

### DETAILED DESCRIPTION

Techniques are described for current balancing. The techniques may be used in a variety of circuits including multi-phase power converters, such as multi-phase DC-DC converters, for example. As described in more detail below, certain examples leverage the synchronous timing signal used in multi-phase power converters as a carrier to deliver current balancing information from one device to another. This approach may avoid complexities associated with some other current balancing methods, and advantageously may be applied in multi-phase DC-DC converters that use internal compensation components.

In some embodiments, a circuit comprises a synchronization terminal, an error amplifier, and a clock generator. The error amplifier is configured to generate a first control voltage signal based on a reference voltage and a power converter output voltage. The clock generator is configured to produce an outgoing clock signal having an outgoing clock frequency. The outgoing clock signal may be used to synchronize timing of current delivery from multiple power converters in a multi-phase power converter system. As described further below, in some examples, the circuit further comprises an encoder coupled to the clock generator and to the synchronization terminal. The encoder is configured to encode the outgoing clock signal based on the first control voltage signal to provide, at the synchronization terminal, an outgoing encoded clock signal. In some examples, in addition to, or alternatively to, the encoder, the circuit comprises a frequency detector and a decoder. The frequency detector is coupled to the synchronization terminal and configured to derive, from an incoming encoded clock signal, an incoming clock frequency. The decoder is coupled to the synchronization terminal and configured to derive, from the incoming encoded clock signal, a second control voltage signal. In a multi-phase power converter, for example, the second control voltage can be used by one or more secondary power converters to replicate the current produced by a primary power converter, so as to achieve current balancing between the two (or more) power converters.

### General Overview

A number of non-trivial issues are associated with performing current balancing in multi-phase circuits, such as multi-phase power converters. One possible current balancing technique in multi-phase DC-DC converters might involve detecting current magnitudes and calculating the average current. The difference between the magnitude of the current in each channel (or phase) and the calculated average current could then be used to generate a current error signal. This current error signal may be added to a voltage error signal to control the output voltage in each channel and correct current imbalance. However, combining output voltage regulation and current balance control on a voltage error signal makes the control more complex. Another approach might involve connecting the error amplifier outputs of each channel together to share a common control voltage. However, this approach would also involve the use of an external trimming circuit because, for each channel, the conversion ratio from the control voltage to the corresponding inductor current is generally unique. In addition, some multi-phase power converters are internally compensated devices wherein the control voltage is not presented at an external pin. This control voltage sharing approach is therefore incompatible with such devices.

Accordingly, current balancing circuits are described herein that avoid the complexities associated with some other approaches and provide a solution that is compatible with internally compensated devices. As described in more detail below, examples of the current balancing circuits and methods described herein can be configured to leverage the internal synchronization (clock) signals that are used to share timing information among channels in multi-phase power converter to encode control voltage information that can be used to precisely (or otherwise sufficiently, for a given application) replicate the inductor current among channels. Various encoding methods can be used, including amplitude modulation or duty cycle modulation (e.g., pulse width modulation) of the clock signal. These encoding techniques can be applied to transfer the control voltage information from one device to another, without compromising or otherwise disrupting the simultaneous transfer of the timing (e.g., clock frequency) information. Complementary decoding methods can be used to extract the encoded control voltage information that may then be used by the receiving device to replicate the current, as described further below.

### Current Balancing Circuits and Methods

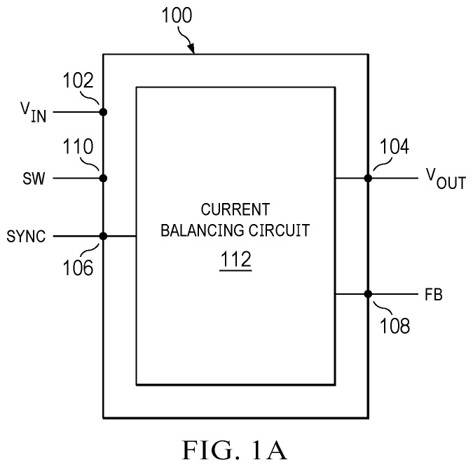

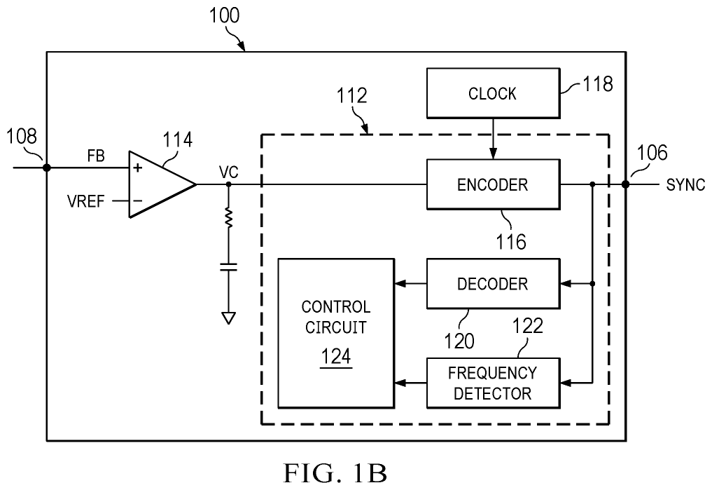

FIG. 1A is a block diagram of a device 100 including a current balancing circuit 112, in one example. The device 100 may be a power converter, such as a DC-DC power converter (e.g., a buck or boost converter), for example. In some examples, the device 100 is an integrated circuit. The device 100 includes a voltage input terminal 102 at which an input voltage, V_{IN}, is received, and a voltage output terminal 104 at which the device provides an output voltage, V_{OUT}. In the illustrated example, the device 100 further includes a synchronization (SYNC) terminal 106 at which a clock signal may be received and/or provided, as described further below. In addition, in some examples, the device 100 includes a feedback (FB) terminal 108 that can be coupled to an error amplifier, as described further below, as well as a switching (SW) terminal 110. In examples in which the device 100 is used in a multi-phase power converter, the switching terminal 110 may be coupled to an inductor in which the corresponding channel current is produced. A multi-phase power converter may comprise a plurality of individual stackable single-phase power converters (e.g., buck converters, boost converters, etc.).

FIG. 1B illustrates an example of the device 100, including the current balancing circuit 112, in one example. In this example, the device 100 includes an error amplifier 114 having a first amplifier input coupled to the FB terminal 108, as described above. The error amplifier 114 further has a second amplifier input that is coupled to a reference terminal to receive a reference voltage, V_{REF}. The error amplifier 114 may be configured to compare a signal received via the FB terminal 108 with the reference voltage, V_{REF}, to produce a control voltage, VC, which is used to generate a channel current. In the illustrated example, the current balancing circuit 112 includes an encoder 116 that is coupled between an amplifier output terminal of the error amplifier 114 and the SYNC terminal 106. A clock generator 118 may be coupled to the encoder 116. As described in more detail below, the encoder 116 can be configured to encode information corresponding to the control voltage, VC, onto a clock signal produced by the clock generator 118 to produce, at the SYNC terminal 106, an encoded outgoing clock signal.

In the example of FIG. 1B, the current balancing circuit 112 further includes a decoder 120 coupled to the SYNC terminal 106 and a frequency detector 122 also coupled to the SYNC terminal 106. The decoder 120 can be used to decode an incoming encoded clock signal (from another device 100, for example) to extract the control voltage information, as described further below. The frequency detector 122 can be used to recover a clock frequency of the incoming encoded clock signal, as also described further below. Outputs of the decoder 120 and the frequency detector 122 are coupled to a control circuit 124. In some examples, the control circuit is configured to control at least certain functionality of the device 100 based on the control voltage information and the clock frequency derived from the incoming encoded clock signal.

In some examples, either the encoder 116 or a combination of the decoder 120 and frequency detector 122 can be enabled, depending on a configuration of the device 100 in a larger circuit or system. For example, if the device 100 is configured as a primary power converter in a multi-phase power converter system, the encoder 116 may be enabled, while the decoder 120, frequency detector 122, and at least some functionality of the control circuit 124 may be disabled. In such instances, the device 100 can be configured to produce an outgoing encoded clock signal at the SYNC terminal 106. In another example, if the device 100 is configured as a secondary power converter in a multi-phase power converter system, the encoder 116 may be disabled, while the decoder 120, frequency detector 122, and the control circuit 124 may be enabled. In such instances, the device 100 can be configured to receive an incoming encoded clock signal at the SYNC terminal 106 and to derive the control voltage, VC, and the clock frequency from the incoming encoded clock signal. Providing the device 100 with both the encoder 116 and the decoder 120 may allow flexibility in the device configuration and use, as noted above. However, in other examples, the device 100 can be constructed including either the encoder 116 or the decoder 120, but not both. Further, the device 100 may include various additional components and/or circuitry are not illustrated in FIG. 1B and/or otherwise be configured differently.

As described above, one application for the device 100 is a multi-phase power converter, such as a multi-phase DC-DC converter. In the modern computing environment, various devices, including central processing units (CPUs), field programmable gate arrays (FPGAs), application-specific integrated circuits (ASICs), and/or peripherals, are becoming more complex, which in some instances increases their power delivery needs. Multi-phase power converters can offer several advantages in terms of ability to deliver higher power with smaller transients, reduced input and/or output capacitance, and/or improved thermal performance and efficiency at high load currents than some high-power single-phase designs.

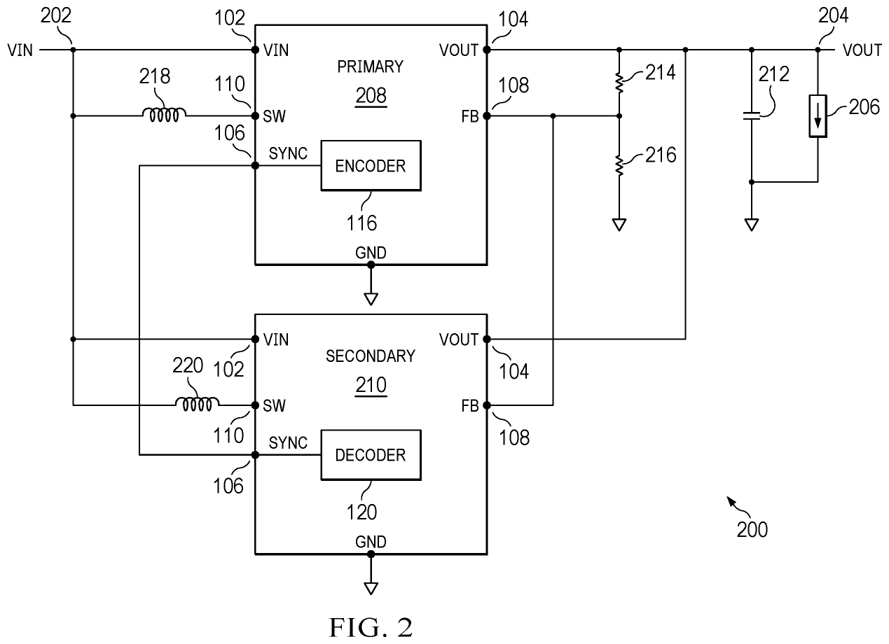

FIG. 2 is a block diagram of a multi-phase DC-DC converter 200 in an example. The multi-phase DC-DC converter 200 includes a plurality of power converters 208 and 210 (e.g., buck or boost converters) coupled together in parallel between a system voltage input terminal 202 and a system voltage output terminal 204. A load 206 is coupled to the system voltage output terminal 204. In the example of FIG. 2, the multi-phase DC-DC converter 200 includes two power converters 208, 210; however, in other examples the multi-phase DC-DC converter 200 may include additional power converters, such as 6, 8, 12 or more power converters coupled in parallel. Thus, individual voltage input terminals 102 of the power converters 208, 210 are coupled to the system voltage input terminal 202, and individual voltage output terminals 104 of the power converters 208, 210 are coupled to the system voltage output terminal 204. Individual power converters may be referred to as a “phase” and each phase may include a set of power transistors, such as power MOSFETs, for example (not shown in FIG. 2) to perform the DC-DC conversion. During steady-state operation, individual power converters are active at phase intervals spaced equally to 360°/n during a switching period, where n is the number of power converters in the system. For example, in the arrangement of FIG. 2, the power converters 208, 210 produce respective output currents that are 180° out of phase. In some examples, the power converters 208 and/or 210 can be implemented using the device 100 described above. The switching period is determined by a switching frequency of the multi-phase DC-DC converter 200.

The group of parallel-connected power converters, in this case, power converters 208 and 210, share a common output capacitor 212 coupled to the system voltage output terminal 204. In some examples, the power converters 208, 210 may also share a common input capacitor (not shown in FIG. 2) coupled to the system voltage input terminal 202. The FB terminals 108 of the individual power converters 208, 210 are coupled to the system voltage output terminal 204 via a voltage divider comprising a pair of resistors 214, 216 coupled in series between the system voltage output terminal 204 and a reference terminal, such as a ground terminal, for example. Further, the individual SW terminals 110 of the power converters 208, 210 are coupled to the system input voltage terminal 202 via respective inductors 218, 220, as shown in FIG. 2.

According to certain examples, one of the power converters, such as the power converter 208 in the example of FIG. 2, is designated as a primary power converter, while the remaining power converters (power converter 210 in the example of FIG. 2) are designated as secondary (dependent) power converters. In the example of FIG. 2, only one secondary power converter 210 is shown; however, in other examples, the multi-phase DC-DC converter 200 may include any number of additional secondary power converters. The primary power converter 208 produces the control voltage, VC, which sets characteristics or parameters of the output current to be supplied to the load 206. The secondary power converter 210 replicates the output current, offset in phase as described above. Accordingly, in certain examples, the secondary power converter 210 receives information from the primary power converter 208 to replicate the control voltage, VC, and therefore produce an output current that is balanced with the output current produced by the primary power converter 208.

As shown in FIG. 2, the SYNC terminals 106 of the primary and secondary power converters 208, 210 are coupled together, such that the secondary power converter 210 can receive the information from the primary power converter 208 via the SYNC terminal 106. In some examples, the primary power converter 208 includes the encoder 116 coupled to the SYNC terminal 106 and configured to encode the clock signal with the control voltage information to produce an encoded clock signal, as described above with reference to FIG. 1B. The secondary power converter 210 includes the decoder 120 coupled to the SYNC terminal 106 and configured to extract the control voltage information from the encoded clock signal, as described above with reference to FIG. 1B.

In some examples, where the primary and secondary power converters 208, 210 are implemented using the device 100, both the primary and secondary power converters 208, 210 may include both the encoder 116 and decoder 120, along with the other components illustrated in FIG. 1B. In such cases, in the primary power converter 208, the decoder 120 may be disabled, while in the secondary power converter 210, the encoder 116 may be disabled. Accordingly, while for simplicity, the primary power converter 208 is shown and described as including circuitry associated with encoding functionality, the primary power converter 208 may also include circuitry associated with decoding functionality that is not used when the device is configured as the primary power converter 208. Similarly, while for simplicity, the secondary power converter 210 is shown and described as including circuitry associated with the decoding functionality, the secondary power converter 210 may also include circuitry associated with the encoding functionality that is not used when the device is configured as the secondary power converter 208.

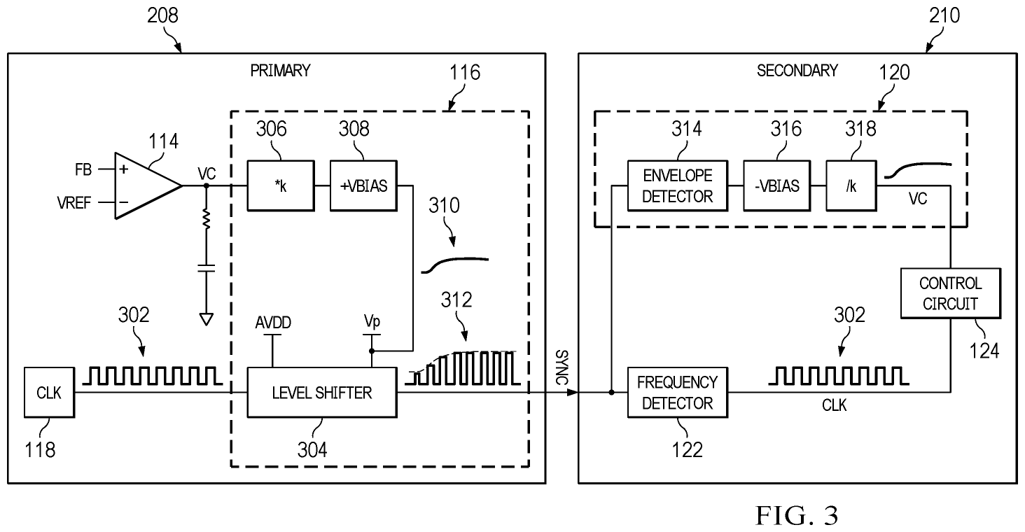

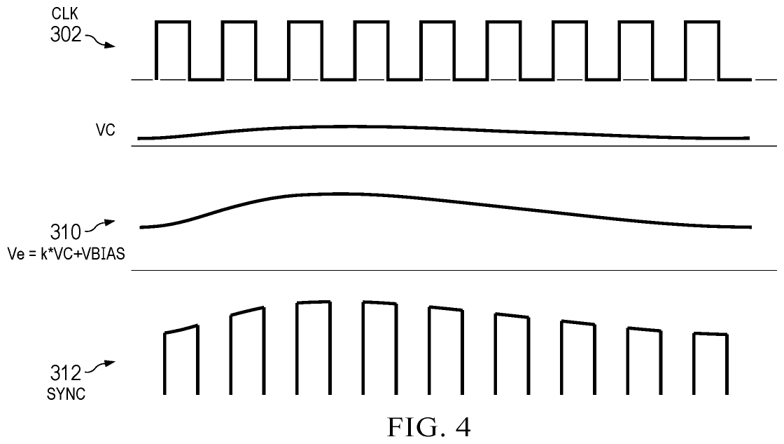

According to certain examples, the primary power converter 208 encodes the control voltage information onto the clock signal using amplitude modulation. An example of this approach is illustrated in FIG. 3. FIG. 4 is a timing diagram showing examples of signals that are produced in the circuitry of FIG. 3 according to some examples.

Referring to FIG. 3, in one example, the primary power converter 208 includes the error amplifier 114 that produces the control voltage, VC, based on a combination of a signal received via the FB terminal 108 and a reference voltage, V_{REF}, and the encoder 116. An example of the control voltage, VC, is shown in FIG. 4. The primary power converter 208 further includes the clock generator 118 that produces a clock signal 302. In some examples, the clock signal 302 is a square wave signal, as shown in FIG. 4, the frequency of which is consistent with the switching frequency of the multi-phase DC-DC converter 200. The encoder 116 is coupled to the outputs of the error amplifier 114 and the clock generator 118.

In this example, the encoder 116 includes a level shifter 304, a multiplier 306, and a bias voltage adjustment element 308. The multiplier 306 and the bias voltage adjustment element 308 together form a first voltage adjuster that operates on the control voltage, VC, output from the error amplifier 114 to produce a modulation signal 310. An example of the modulation signal 310 is shown in FIG. 4. In one example, the multiplier 306 multiplies the control voltage, VC, by a constant, k. The constant, k, may be any positive integer or non-integer value. In some examples, the multiplier 306 is used to provide noise immunity by raising the voltage level of the control voltage, VC, signal before it is used to modulate the clock signal 302. The bias voltage adjustment element 308 superimposes a bias voltage onto the level-adjusted (e.g., multiplied by k) control voltage, VC, signal to produce the modulation signal 310.

In some examples, the level shifter 304 level shifts the clock signal 302 and modulates the amplitude of the level-shifted clock signal 302 to produce an encoded clock signal 312. Prior to modulation with the modulation signal 310, the level shifter 304 increases the amplitude (level shifts) the clock signal 302 such that the applied amplitude modulation does not cause the HIGH level (e.g., corresponding to logic 1) of the square wave to potentially fall so low as to be confused with the LOW level (e.g., corresponding to logic 0), which could cause frequency errors in the secondary power converter 210. The encoded clock signal 312 produced at the SYNC terminal 106 of the primary power converter 208 thus has a voltage that is proportional to the control voltage, VC, and superimposed with the bias voltage, Vbias. In examples, the amplitude modulation affects only the HIGH level of the square wave, and the frequency of the clock signal 302 thus remains unchanged by encoding of the control voltage information. An example of the encoded clock signal 312 is shown in FIG. 4.

Still referring to FIG. 3, in this example, the secondary power converter 201 includes the frequency detector 122, the decoder 120, and the control circuit 124. The frequency detector 122 is coupled to the SYNC terminal 106 of the secondary power converter 210, which is coupled to the SYNC terminal 106 of the primary power converter 208, as shown in FIG. 2. The frequency detector 122 is configured to recover the frequency of the clock signal 302 from the encoded clock signal 312. To accomplish this functionality, in one example, the frequency detector 122 includes a threshold detection circuit that can be configured to detect either the rising edges or falling edges of the pulses in the square wave, and thereby recover the frequency.

According to certain examples, the decoder 120 includes an envelope detector 314, a bias voltage adjustment element 316, and a divider 318. The envelope detector 314 is coupled to the SYNC terminal 106 and receives the encoded clock signal 312. The envelope detector recovers the voltage envelope of the encoded clock signal, thereby producing a signal that has a voltage that is proportional to the control voltage, VC, of the primary power converter 208 and superimposed with the bias voltage, Vbias. Accordingly, the bias voltage adjustment element 316 is configured to subtract the bias voltage, Vbias, from the signal output by the envelope detector. The divider 318 may divide the resulting signal output from the bias voltage adjustment element 316 by the constant, k. Thus, together the bias voltage adjustment element 316 and the divider 318 form a second voltage adjuster that, with the envelope detector 314, can recover the control voltage, VC, of the primary power converter 208.

In some examples, the recovered control voltage, VC, and the recovered frequency of the clock signal 302 are input to the control circuit 124. Using this information, the control circuit may control various components and circuitry of the secondary power converter 210 to produce an output current that precisely or otherwise sufficiently (e.g., within a tolerance of 5% or less) replicates the current output by the primary power converter 208.

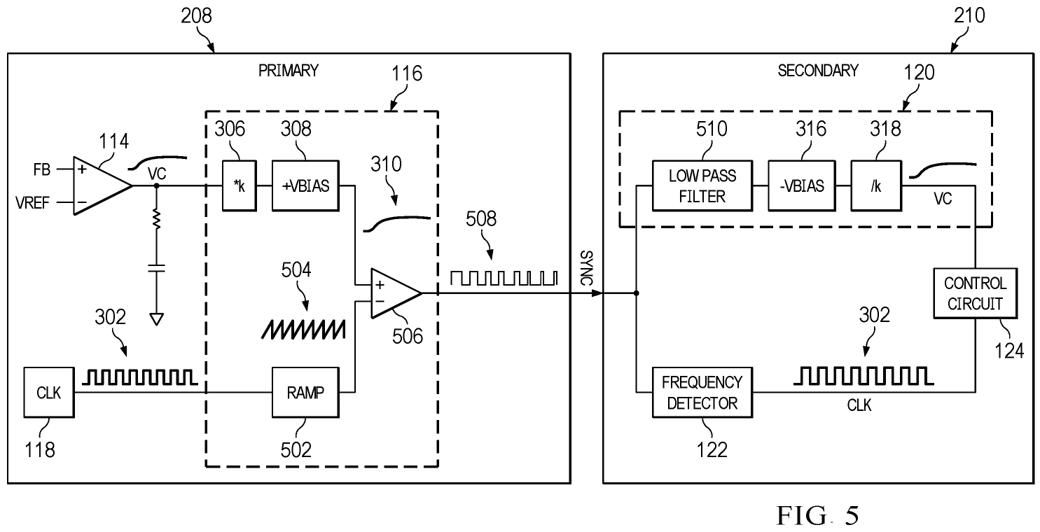

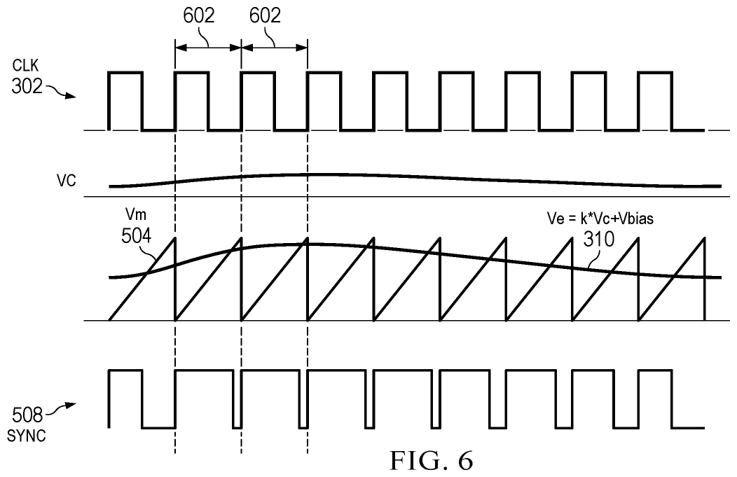

According to another example, the primary power converter 208 encodes the control voltage information onto the clock signal 302 by modulating the duty cycle, rather than the amplitude, of the clock signal 302. An example of this approach is illustrated in FIG. 5. FIG. 6 is a timing diagram showing examples of signals that are produced in the circuitry of FIG. 5 according to some examples.

Referring to FIG. 5, in this example, the encoder 116 in the primary device 208 includes a ramp generator 502 coupled to the output of the clock generator 118 and configured to produce a ramp signal 504 based on the clock signal 302. In one example, the ramp signal 504 has a voltage, Vm, as shown in FIG. 6. The encoder 116 further includes the multiplier 306 and the bias voltage adjustment element 308 that together produce the modulation signal 310, as described above with reference to FIG. 3. Thus, the modulation signal 310 has a voltage, Ve, that is proportional to the control voltage, VC, and superimposed with the bias voltage, Vbias, as shown in FIG. 6.

In the example of FIG. 5, the encoder 116 further includes a comparator 506 that has one input coupled to the output of the ramp generator 502 and another input coupled to the output of the bias voltage adjustment element 308. The comparator 506 may be configured to compare the voltage, Ve, of the modulation signal 310 with the voltage, Vm, of the ramp signal 502 to produce an encoded clock signal 508. In one example, the encoded clock signal 508 is a square wave signal with a variable duty cycle, as shown in FIG. 6. The frequency 602 of the encoded clock signal 508 is the same as the frequency of the clock signal 302 because the ramp signal 504 is produced based on the clock signal 302. However, the duty cycle is modulated by the modulation signal 310 to encode the control voltage, VC. As shown in FIG. 6, in this example, the duty cycle increases (more time at the HIGH or logic 1 level) with increasing voltage Ve (and therefore VC).

Further, in this example, the secondary power converter 210 includes the frequency detector 122 coupled to the SYNC terminal 106, as described above. Since the frequency of the encoded clock signal 508 corresponds to that of the clock signal 302, the frequency detector 122 can recover the frequency of the clock signal 302, as described above. The recovered frequency can be used by the control circuit 124 to synchronize timing of operation of the secondary power converter with the primary power converter 208, as is the case in the example of FIG. 3.

In some examples, the decoder 120 includes a low pass filter 510 in combination with the bias voltage adjustment element 316, and a divider 318. The low pass filter 510 is coupled to the SYNC terminal 106 and filters the encoded clock signal 508 to recover a signal presentative of the modulation signal 310 and thus having a voltage that is proportional to the control voltage, VC, of the primary power converter 208 and superimposed with the bias voltage, Vbias. Accordingly, the bias voltage adjustment element 316 is configured to subtract the bias voltage, Vbias, from the signal output by the low pass filter 510. The divider 318 may divide the resulting signal output from the bias voltage adjustment element 316 by the constant, k, as described above. Thus, the decoder 120 can recover the control voltage, VC, of the primary power converter 208, which may then be provide to the control circuit 124.

As described above, the control circuit may use the recovered control voltage, VC, and frequency of the clock signal 302 to control various components and circuitry of the secondary power converter 210 to produce an output current that precisely or otherwise sufficiently (e.g., within a tolerance of 5% or less) replicates the current output by the primary power converter 208.

Thus, using either amplitude or duty cycle modulation, the clock signal 302 of the primary power converter 208 can be encoded with the control voltage of the primary power converter 208, and used to transfer the control voltage information to the secondary power converter 210 (and any additional secondary power converters that may be used in the multi-phase DC-DC converter 200). In this manner, precise current balancing can be achieved among the individual power converters of the multi-phase DC-DC converter 200, without requiring complex control schemes or an external pin/terminal to access the control voltage.

### Further Examples

Example 1 is a circuit comprising an error amplifier configured to generate a first control voltage signal based on a reference voltage and a power converter output voltage, a synchronization terminal, a clock generator configured to produce an outgoing clock signal having an outgoing clock frequency, and an encoder coupled to the clock generator and to the synchronization terminal, the encoder configured to encode the outgoing clock signal based on the first control voltage signal to provide, at the synchronization terminal, an outgoing encoded clock signal. In this example, the circuit further comprises a frequency detector coupled to the synchronization terminal and configured to derive, from an incoming encoded clock signal, an incoming clock frequency, and a decoder coupled to the synchronization terminal and configured to derive, from the incoming encoded clock signal, a second control voltage signal.

Example 2 includes the circuit of Example 1, further comprising a control circuit coupled to the frequency detector and to the decoder and configured to control a DC-DC converter based on the second control voltage signal and the incoming clock frequency.

Example 3 includes the circuit of one of Examples 1 or 2, wherein the encoder is configured to modulate, based on the first control voltage signal, at least one of an amplitude of the outgoing clock signal or a duty cycle of the outgoing clock signal to produce the outgoing encoded clock signal.

Example 4 includes the circuit of any one of Examples 1-3, wherein the encoder comprises a level shifter configured to modulate an amplitude of the outgoing clock signal based on the first control voltage signal to produce the outgoing encoded clock signal.

Example 5 includes the circuit of Example, 4, wherein the encoder comprises a voltage adjuster coupled to an output of the error amplifier and to the level shifter, the voltage adjuster configured to produce a modulation signal by superimposing a bias voltage onto the first control voltage signal, and wherein the level shifter is configured to modulate the amplitude of the clock signal based on the modulation signal.

Example 6 includes the circuit of Example 5, wherein the voltage adjuster is a first voltage adjuster, and wherein the decoder comprises an envelope detector, and a second voltage adjuster coupled to an output of the envelope detector and configured to subtract the bias voltage from a signal output by the envelop detector to recover the second control voltage signal.

Example 7 includes the circuit of Example 6, wherein the first voltage adjuster multiplies an amplitude of the first control voltage signal by a constant to produce the modulation signal, and the second voltage adjuster divides out the constant to recover the second control voltage signal.

Example 8 includes the circuit of Example 4, wherein the decoder comprises an envelope detector.

Example 9 includes the circuit of any one of Examples 1-3, wherein the encoder comprises a ramp generator coupled to the clock generator and configured to produce a ramp signal based on the outgoing clock signal, and a comparator configured to compare the ramp signal with a modulation signal to produce the outgoing encoded clock signal, the modulation signal being based on the first control voltage signal.

Example 10 includes the circuit of Example 9, wherein the decoder comprises a low pass filter.

Example 11 includes the circuit of Example 10, wherein the encoder comprises a voltage adjuster coupled to an output of the error amplifier and configured to produce the modulation signal by superimposing a bias voltage onto the first control voltage signal.

Example 12 includes the circuit of Example 11, wherein the voltage adjuster is a first voltage adjuster, and the decoder comprises a second voltage adjuster coupled to an output of the low pass filter and configured to subtract the bias voltage from a signal output from the low pass filter to recover the second control voltage signal.

Example 13 includes the circuit of Example 12, wherein the first voltage adjuster multiplies an amplitude of the first control voltage signal by a constant to produce the modulation signal, and the second voltage adjuster divides out the constant to recover the second control voltage signal.

Example 14 includes the circuit of any one of Examples 1-13, wherein the frequency detector includes a threshold detection circuit.

Example 15 includes the circuit of any one of Examples 1-14, wherein the first control voltage signal is associated with a first current, and the second control voltage signal is associated with a second current, and the second current matches the first current within a tolerance of 5% or less.

Example 16 includes the circuit of any one of Examples 1-15, wherein the first control voltage signal is associated with a first current, and the second control voltage signal is associated with a second current, and the second current is offset in phase from the first current by 180 degrees, within a 2 degree tolerance.

Example 17 is a multi-phase DC-DC converter comprising the circuit of any one of Examples 1-16.

Example 18 includes the multi-phase DC-DC converter of Example 17, wherein the multi-phase DC-DC converter includes at least one buck converter.

Example 19 is a multi-phase DC-DC converter system comprising a first DC-DC converter having a first input terminal for receiving an input voltage, a first synchronization terminal, a feedback terminal, and a first output terminal. The first DC-DC converter includes an amplifier having an input terminal coupled to the feedback terminal, a clock generator, and a level shifter having an input coupled to an output of the clock generator and to an output of the amplifier, and an output coupled to the first synchronization terminal. The multi-phase DC-DC converter further comprises a second DC-DC converter having a second input terminal for receiving the input voltage, a second synchronization terminal coupled to the first synchronization terminal, and a second output terminal coupled to the first output terminal. The second DC-DC converter includes a frequency detector coupled to the second synchronization terminal, an envelope detector coupled to the second synchronization terminal, and a control circuit coupled to the frequency detector and to the envelope detector.

Example 20 includes the system of Example 19, wherein the first DC-DC converter is configured to produce, at the first output terminal, a first output signal having an output voltage and a first current; and wherein the control circuit is configured to control the second DC-DC converter to produce, at the second output terminal, a second output signal having the output voltage and a second current that is phase-shifted relative to the first current.

Example 21 includes the system of Example 20, wherein the phase shift is 180° within a 2° tolerance.

Example 22 includes the system of any one of Examples 19-21, wherein the amplifier is configured to produce a control voltage based on a signal received at the feedback terminal; wherein the clock generator is configured to produce a clock signal having a clock frequency; and wherein the level shifter is configured to produce, at the first synchronization terminal, a synchronization signal based on the clock signal and the control voltage.

Example 23 includes the system of Example 22, wherein the frequency detector is configured to recover the clock frequency from the synchronization signal, and wherein the control circuit is configured to synchronize, based on the clock frequency, a second output signal produced by the second DC-DC converter at the second output terminal with a first output signal produced by the first DC-DC converter at the first output terminal.

Example 24 includes the system of one of Examples 22 or 23, wherein the first DC-DC converter comprises a first voltage adjuster coupled between the amplifier and the level shifter.

Example 25 includes the system of Example 24, wherein the second DC-DC converter comprises a second voltage adjuster coupled to the envelope detector, and wherein the envelope detector and the second voltage adjuster are configured to recover the control voltage from the synchronization signal.

Example 26 includes the system of Example 25, wherein the first voltage adjuster comprises a multiplier configured to multiply the control voltage by a constant to produce a modified control voltage, and a summation block configured to superimpose a bias voltage onto the modified control voltage.

Example 27 includes the system of Example 26, wherein the second voltage adjuster comprises a subtraction block configured to subtract the bias voltage from a signal output by the envelope detector to produce an intermediate signal, and a divider configured to divide the intermediate signal by the constant to recover the control voltage.

Example 28 is a multi-phase DC-DC converter system comprising a first DC-DC converter having a first input terminal for receiving an input voltage, a first synchronization terminal, a feedback terminal, and a first output terminal. The first DC-DC converter includes an amplifier having an input terminal coupled to the feedback terminal, a clock generator, a ramp generator coupled to a clock output terminal of the clock generator, and a comparator having a first comparator input terminal coupled to an amplifier output terminal of the amplifier, a second comparator input terminal coupled to a ramp output terminal of the ramp generator, and a comparator output terminal coupled to the first synchronization terminal. The system further comprises a second DC-DC converter having a second input terminal for receiving the input voltage, a second synchronization terminal coupled to the first synchronization terminal, and a second output terminal coupled to the first output terminal. The second DC-DC converter includes a frequency detector coupled to the second synchronization terminal, a low pass filter coupled to the second synchronization terminal, and a control circuit coupled to the frequency detector and to the low pass filter.

Example 29 includes the system of Example 28, wherein the first DC-DC converter further comprises a first voltage adjuster coupled between the amplifier and the first comparator input terminal.

Example 30 includes the system of Example 29, wherein the second DC-DC converter comprises a second voltage adjuster coupled between a filter output terminal of the low pass filter and the control circuit.

Example 31 includes the system of any one of Examples 38-30 wherein the amplifier is configured to produce a control voltage based on a signal received at the feedback terminal, wherein the clock generator is configured to produce a clock signal having a clock frequency, and wherein the ramp generator is configured to produce a ramp signal based on the clock signal.

Example 32 includes the system of Example 31, wherein the comparator is configured to produce, at the first synchronization terminal, a synchronization signal based on the control voltage and the ramp signal.

Example 33 includes the system of Example 32, wherein the low pass filter is configured to filter the synchronization signal to recover the control voltage.

Example 34 includes the system of Example 33, wherein the frequency detector is configured to recover the clock frequency based on the synchronization signal.

Example 35 includes the system of Example 34, wherein the first DC-DC converter is configured to produce, at the first output terminal, a first output signal having an output voltage and a first current, and wherein the control circuit is configured to control the second DC-DC converter, based on the clock frequency and the control voltage, to produce, at the second output terminal, a second output signal having the output voltage and a second current that is phase-shifted relative to the first current.

Example 36 is a circuit comprising an error amplifier configured to generate a first control voltage signal based on a reference voltage and a power converter output voltage, a synchronization terminal, a clock generator configured to produce an outgoing clock signal having an outgoing clock frequency, and an encoder coupled to the clock generator and to the synchronization terminal, the encoder configured to encode the outgoing clock signal based on the first control voltage signal to provide, at the synchronization terminal, an outgoing encoded clock signal.

Example 37 is a circuit comprising a synchronization terminal, a frequency detector coupled to the synchronization terminal and configured to derive, from an incoming encoded clock signal, an incoming clock frequency, a decoder coupled to the synchronization terminal and configured to derive, from the incoming encoded clock signal, a control voltage signal, and a control circuit coupled to the frequency detector and to the decoder and configured to control a DC-DC converter based on the control voltage signal and the incoming clock frequency.

Example 38 is a multi-phase DC-DC converter comprising a first DC-DC converter having a synchronization terminal and a first output terminal and configured to produce, at the first output terminal, a first output signal having a first current and an output voltage, and a second DC-DC converter having a second output terminal. The first DC-DC converter comprises a clock generator configured to produce a clock signal having a clock frequency, and an encoder coupled to the clock generator and to the synchronization terminal, the encoder configured to encode the clock signal based on a control voltage of the first DC-DC converter to provide, at the synchronization terminal, an encoded clock signal. The second DC-DC converter comprises a frequency detector coupled to the synchronization terminal of the first DC-DC converter and configured to derive, from the encoded clock signal, the clock frequency, a decoder coupled to the synchronization terminal of the first DC-DC converter and configured to derive, from the encoded clock signal, the control voltage, and a control circuit coupled to the frequency detector and to the decoder and configured to control the second DC-DC converter based on the control voltage and the clock frequency to produce, at the second output terminal, a second output signal having the output voltage and a second current balanced and synchronized with the first current.

Example 39 includes the multi-phase DC-DC converter of Example 38, wherein the encoder is configured to modulate, based on the control voltage, least one of an amplitude of the clock signal or a duty cycle of the clock signal to produce the encoded clock signal.

Example 40 includes the multi-phase DC-DC converter of one of Examples 38 or 39, wherein the encoder comprises a level shifter configured to modulate an amplitude of the clock signal based on the control voltage to produce the encoded clock signal.

Example 41 includes the multi-phase DC-DC converter of Example 40, wherein the first DC-DC converter further comprises an error amplifier configured to produce the control voltage, and wherein the encoder comprises a first voltage adjuster coupled to an output of the error amplifier and to the level shifter, the first voltage adjuster configured to produce a modulation signal by superimposing a bias voltage onto the control voltage, and wherein the level shifter is configured to modulate the amplitude of the clock signal based on the modulation signal.

Example 42 includes the multi-phase DC-DC converter of Example 41, wherein the decoder comprises an envelope detector and a second voltage adjuster coupled to an output of the envelope detector and configured to subtract the bias voltage from a signal output by the envelop detector to recover the control voltage.

Example 43 includes the multi-phase DC-DC converter of Example 42, wherein the first voltage adjuster multiplies an amplitude of the control voltage signal by a constant to produce the modulation signal, and the second voltage adjuster divides out the constant to recover the control voltage.

Example 44 includes the multi-phase DC-DC converter of one of Examples 38 or 39, wherein the encoder comprises a ramp generator coupled to the clock generator and configured to produce a ramp signal based on the clock signal, and a comparator configured to compare the ramp signal with a modulation signal to produce the encoded clock signal, the modulation signal being based on the control voltage.

Example 45 includes the multi-phase DC-DC converter of Example 44, wherein the decoder comprises a low pass filter.

Example 46 includes the multi-phase DC-DC converter of Example 45, wherein the first DC-DC converter further comprises an error amplifier configured to produce the control voltage, and wherein the encoder comprises a first voltage adjuster coupled to an output of the error amplifier and to the level shifter, the first voltage adjuster configured to produce a modulation signal by superimposing a bias voltage onto the control voltage, and wherein the level shifter is configured to modulate the amplitude of the clock signal based on the modulation signal.

Example 47 includes the multi-phase DC-DC converter of Example 46, wherein the decoder further comprises a second voltage adjuster coupled to an output of the low pass filter and configured to subtract the bias voltage from a signal output by the low pass filter to recover the control voltage.

Example 48 includes the multi-phase DC-DC converter of Example 47, wherein the first voltage adjuster multiplies an amplitude of the control voltage signal by a constant to produce the modulation signal, and the second voltage adjuster divides out the constant to recover the control voltage.

Example 49 includes the multi-phase DC-DC converter of any one of Examples 38-48, wherein the frequency detector includes a threshold detection circuit.

Example 50 is an integrated circuit (IC) including the circuit of any one of Examples 1 through 16, 36, or 37, or the multi-phase DC-DC converter of any of Examples 17, 18, or 38-49, or the multi-phase DC-DC converter system of any one of Examples 19 through 35.

Example 51 is a printed circuit board (PCB) including the circuit of any one of Examples 1 through 16, 36, or 37, or the multi-phase DC-DC converter of any of Examples 17, 18, or 38-49, or the multi-phase DC-DC converter system of any one of Examples 19 through 35.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, such as by an end user and/or a third party.

While the use of particular transistors is described herein, other transistors (or equivalent devices) may be used instead. For example, a p-channel field effect transistor (PFET) may be used in place of an n-channel field effect transistor (NFET) with little or no changes to the circuit. Furthermore, other types of transistors may be used (such as bipolar junction transistors (BJTs)). Furthermore, the devices may be implemented in/over a silicon substrate (Si), a silicon carbide substrate (SiC), a gallium nitride substrate (GaN) or a gallium arsenide substrate (GaAs). Moreover, reference to transistor features such as gate, source, or drain is not intended to exclude any suitable transistor technologies. For instance, features such as source, drain, and gate are typically used to refer to a FET, while emitter, collector, and base are typically used to refer to a BJT. Such features may be used interchangeably herein. For instance, reference to the gate of a transistor may refer to either the gate of a FET or the base of a BJT, and vice-versa. In some examples, a control terminal may refer to either the gate of a FET or the base of a BJT. Any other suitable transistor technologies can be used. Any such transistors can be used as a switch, with the gate or base or other comparable feature acting as a switch select input that can be driven to connect the source and drain (or the emitter and collector, as the case may be).

References herein to a field effect transistor (FET) being “ON” (or a switch being closed) means that the conduction channel of the FET is present, and drain current may flow through the FET. References herein to a FET being “OFF” (or a switch being open) means that the conduction channel is not present, and drain current does not flow through the FET. A FET that is OFF, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter.

Modifications are possible in the described examples, and other examples are possible within the scope of the claims.

What is claimed is:

1. A circuit comprising:
an error amplifier configured to generate a first control voltage signal based on a reference voltage and a power converter output voltage;
a synchronization terminal;
a clock generator configured to produce an outgoing clock signal having an outgoing clock frequency;
an encoder coupled to the clock generator and to the synchronization terminal, the encoder configured to encode the outgoing clock signal based on the first control voltage signal to provide, at the synchronization terminal, an outgoing encoded clock signal;
a frequency detector coupled to the synchronization terminal and configured to derive, from an incoming encoded clock signal, an incoming clock frequency; and
a decoder coupled to the synchronization terminal and configured to derive, from the incoming encoded clock signal, a second control voltage signal.

2. The circuit of claim 1, further comprising a control circuit coupled to the frequency detector and to the decoder and configured to control a DC-DC converter based on the second control voltage signal and the incoming clock frequency.

3. The circuit of claim 1, wherein the encoder is configured to modulate, based on the first control voltage signal, at least one of an amplitude of the outgoing clock signal or a duty cycle of the outgoing clock signal to produce the outgoing encoded clock signal.

4. The circuit of claim 1, wherein the encoder comprises a level shifter configured to modulate an amplitude of the outgoing clock signal based on the first control voltage signal to produce the outgoing encoded clock signal.

5. The circuit of claim 4, wherein the encoder comprises a first voltage adjuster coupled to an output of the error amplifier and to the level shifter, the first voltage adjuster configured to produce a modulation signal by superimposing a bias voltage onto the first control voltage signal, and wherein the level shifter is configured to modulate the amplitude of the clock signal based on the modulation signal; and
wherein the decoder comprises an envelope detector and a second voltage adjuster coupled to an output of the envelope detector and configured to subtract the bias voltage from a signal output by the envelop detector to recover the second control voltage signal.

6. The circuit of claim 5, wherein the first voltage adjuster multiplies an amplitude of the first control voltage signal by a constant to produce the modulation signal, and the second voltage adjuster divides out the constant to recover the second control voltage signal.

7. The circuit of claim 4, wherein the decoder comprises an envelope detector.

8. The circuit of claim 1, wherein the encoder comprises:
a ramp generator coupled to the clock generator and configured to produce a ramp signal based on the outgoing clock signal; and
a comparator configured to compare the ramp signal with a modulation signal to produce the outgoing encoded clock signal, the modulation signal being based on the first control voltage signal.

9. The circuit of claim 8, wherein the decoder comprises a low pass filter.

10. The circuit of claim 9, wherein the encoder comprises a first voltage adjuster coupled to an output of the error amplifier and configured to produce the modulation signal by superimposing a bias voltage onto the first control voltage signal; and
wherein the decoder comprises a second voltage adjuster coupled to an output of the low pass filter and configured to subtract the bias voltage from a signal output from the low pass filter to recover the second control voltage signal.

11. The circuit of claim 10, wherein the first voltage adjuster multiplies an amplitude of the first control voltage signal by a constant to produce the modulation signal, and the second voltage adjuster divides out the constant to recover the second control voltage signal.

12. A multi-phase DC-DC converter system comprising:
a first DC-DC converter having a first input terminal for receiving an input voltage, a first synchronization terminal, a feedback terminal, and a first output terminal, the first DC-DC converter including
an amplifier having an input terminal coupled to the feedback terminal,
a clock generator, and
a level shifter having an input coupled to an output of the clock generator and to an output of the amplifier, and an output coupled to the first synchronization terminal; and
a second DC-DC converter having a second input terminal for receiving the input voltage, a second synchronization terminal coupled to the first synchronization terminal, and a second output terminal coupled to the first output terminal, the second DC-DC converter including
a frequency detector coupled to the second synchronization terminal,
an envelope detector coupled to the second synchronization terminal, and
a control circuit coupled to the frequency detector and to the envelope detector.

13. The system of claim 12, wherein the first DC-DC converter is configured to produce, at the first output terminal, a first output signal having an output voltage and a first current; and wherein the control circuit is configured to control the second DC-DC converter to produce, at the second output terminal, a second output signal having the output voltage and a second current that is phase-shifted relative to the first current.

14. The system of claim 12, wherein the amplifier is configured to produce a control voltage based on a signal received at the feedback terminal; wherein the clock generator is configured to produce a clock signal having a clock frequency; and wherein the level shifter is configured to produce, at the first synchronization terminal, a synchronization signal based on the clock signal and the control voltage.

15. The system of claim 14, wherein the frequency detector is configured to recover the clock frequency from the synchronization signal; and wherein the control circuit is configured to synchronize, based on the clock frequency, a second output signal produced by the second DC-DC converter at the second output terminal with a first output signal produced by the first DC-DC converter at the first output terminal.

16. The system of claim 14, wherein the first DC-DC converter comprises a first voltage adjuster coupled between the amplifier and the level shifter; and wherein the second DC-DC converter comprises a second voltage adjuster coupled to the envelope detector; wherein the envelope detector and the second voltage adjuster are configured to recover the control voltage from the synchronization signal.

17. The system of claim 16, wherein the first voltage adjuster comprises a multiplier configured to multiply the control voltage by a constant to produce a modified control voltage, and a summation block configured to superimpose a bias voltage onto the modified control voltage; and
wherein the second voltage adjuster comprises a subtraction block configured to subtract the bias voltage from a signal output by the envelope detector to produce an intermediate signal, and a divider configured to divide the intermediate signal by the constant to recover the control voltage.

18. A multi-phase DC-DC converter system comprising:
a first DC-DC converter having a first input terminal for receiving an input voltage, a first synchronization terminal, a feedback terminal, and a first output terminal, the first DC-DC converter including
an amplifier having an input terminal coupled to the feedback terminal,
a clock generator,
a ramp generator coupled to a clock output terminal of the clock generator, and
a comparator having a first comparator input terminal coupled to an amplifier output terminal of the amplifier, a second comparator input terminal coupled to a ramp output terminal of the ramp generator, and a comparator output terminal coupled to the first synchronization terminal; and
a second DC-DC converter having a second input terminal for receiving the input voltage, a second synchronization terminal coupled to the first synchronization terminal, and a second output terminal coupled to the first output terminal, the second DC-DC converter including
a frequency detector coupled to the second synchronization terminal,
a low pass filter coupled to the second synchronization terminal, and
a control circuit coupled to the frequency detector and to the low pass filter.

19. The system of claim 18, wherein the first DC-DC converter further comprises a first voltage adjuster coupled between the amplifier and the first comparator input terminal; and wherein the second DC-DC converter comprises a second voltage adjuster coupled between a filter output terminal of the low pass filter and the control circuit.

20. The system of claim 18, wherein the amplifier is configured to produce a control voltage based on a signal received at the feedback terminal; wherein the clock generator is configured to produce a clock signal having a clock frequency; and wherein the ramp generator is configured to produce a ramp signal based on the clock signal.

21. The system of claim 20, wherein the comparator is configured to produce, at the first synchronization terminal, a synchronization signal based on the control voltage and the ramp signal.

22. The system of claim 21, wherein the low pass filter is configured to filter the synchronization signal to recover the control voltage.

23. The system of claim 22, wherein the frequency detector is configured to recover the clock frequency based on the synchronization signal.

24. The system of claim 23, wherein the first DC-DC converter is configured to produce, at the first output terminal, a first output signal having an output voltage and a first current; and wherein the control circuit is configured to control the second DC-DC converter, based on the clock frequency and the control voltage, to produce, at the second output terminal, a second output signal having the output voltage and a second current that is phase-shifted relative to the first current.
